(19) United States
(12) Patent Application Publication
(10) Pub. No.: US 2026/0076111 A1
(43) Pub. Date: Mar. 12, 2026

(54) SUBSTRATE CHUCKING WITH MULTISCALE WAFER STRESS MODULATION

(71) Applicant: Applied Materials, Inc., Santa Clara, CA (US)

(72) Inventors: Pradeep Kumar Subrahmanyan, San Jose, CA (US); Wonjae Lee, Fremont, CA (US)

(21) Appl. No.: 19/079,202

(22) Filed: Mar. 13, 2025

Related U.S. Application Data
(60) Provisional application No. 63/693,634, filed on Sep. 11, 2024.

(51) Int. Cl. H01L 21/02; G01B 11/16; H01L 21/66; H01L 21/67

(52) U.S. Cl. CPC H10P 14/6536; G01B 11/16; H10P 14/69433; H10P 72/0616; H10P 74/203

(57) ABSTRACT

Disclosed systems and techniques are directed to improving chucking of substrates using stress-compensation beams with multiscale irradiation doses. The techniques include decomposing a profile of a deformation of a substrate into a plurality of harmonics, and identifying, using chuckability reference data, one or more harmonics of the plurality of harmonics having an amplitude above a maximum amplitude capable of being flattened by a predetermined clamping pressure exerted on the substrate by a chuck. The techniques further include determining, based at least on a subset of the one or more harmonics, settings of a stress-modulation beam, forming a stress-compensation layer (SCL) on the substrate causing a modification of the deformation of the substrate, and irradiating the SCL with the stress-modulation beam, wherein the stress-modulation beam causes a reduction of the deformation of the substrate.

### RELATED APPLICATIONS

This application claims the benefit of the U.S. Provisional Patent Application No. 63/693,634, entitled “WAFER CHUCKING IMPROVEMENT WITH MULTI SCALE WAFER STRESS MODULATION” filed Sep. 11, 2024, the entire contents of which are being incorporated in their entirety by reference herein.

### TECHNICAL FIELD

The disclosure pertains to semiconductor manufacturing, including processing of substrates and devices manufactured thereon.

### BACKGROUND

Modern semiconducting devices, such as processing units, memory devices, light detectors, solar cells, light-emitting semiconductor devices, devices that deploy complementary metal-oxide-semiconductor (CMOS) structures, and the like, are often manufactured on silicon wafers (or other suitable substrates). Wafers may undergo numerous processing operations, such as physical vapor deposition, chemical vapor deposition, etching, photo-masking, polishing, and/or various other operations. In a continuous effort to reduce the cost of semiconductor devices, multi-layer stacks of dies, insulating films, patterned and/or doped semiconducting films, and/or other features are often deposited on a single wafer, resulting in high aspect ratio devices, which are used, e.g., in 3D flash memory devices and other applications. Deposition, patterning, etching, polishing, etc., of stacks of multi-layered structures often result in significant stresses applied to the underlying wafers. Such stresses lead to both an out-of-plane distortion and an in-plane distortion of features supported by the wafers. These distortions result in misalignment of deposited features and can significantly degrade quality of manufactured devices.

### SUMMARY

Disclosed herein, according to one embodiment, is a method that includes decomposing a profile of a deformation of a substrate into a plurality of harmonics and identifying, using chuckability reference data, one or more harmonics of the plurality of harmonics having an amplitude above a maximum amplitude capable of being flattened by a predetermined clamping pressure exerted on the substrate by a chuck. The method further includes determining, based at least on a subset of the one or more harmonics, settings of a stress-modulation beam, forming a stress-compensation layer (SCL) on the substrate, wherein the SCL causes a modification of the deformation of the substrate, and irradiating the SCL with the stress-modulation beam, wherein the stress-modulation beam causes a reduction of the deformation of the substrate.

In another embodiment, disclosed is a system that includes a memory and a processing device communicatively coupled to the memory. The processing device causes performance of operations that include decomposing a profile of a deformation of a substrate into a plurality of harmonics and identifying, using chuckability reference data, one or more harmonics of the plurality of harmonics having an amplitude above a maximum amplitude capable of being flattened by a predetermined clamping pressure exerted on the substrate by a chuck. The operations further include determining, based at least on a subset of the one or more harmonics, settings of a stress-modulation beam, forming an SCL on the substrate, wherein the SCL causes a modification of the deformation of the substrate, and irradiating the SCL with the stress-modulation beam, wherein the stress-modulation beam causes a reduction of the deformation of the substrate.

In another embodiment, disclosed is a semiconductor manufacturing system that includes one or more processing chambers. The semiconductor manufacturing system is to decompose a profile of a deformation of a substrate into a plurality of harmonics and identify, using chuckability reference data, one or more harmonics of the plurality of harmonics having an amplitude above a maximum amplitude capable of being flattened by a predetermined clamping pressure exerted on the substrate by a chuck. The system is further to determine, based at least on a subset of the one or more harmonics, settings of a stress-modulation beam, form a stress-compensation layer (SCL) on the substrate, wherein the SCL causes a modification of the deformation of the substrate, and irradiate the SCL with the stress-modulation beam, wherein the stress-modulation beam causes a reduction of the deformation of the substrate.

### BRIEF DESCRIPTION OF THE DRAWINGS

The present disclosure will be understood more fully from the detailed description given below and from the accompanying drawings of various embodiments of the disclosure.

FIG. 1A illustrates an example sectional view of a processing chamber capable of deploying a chuck to hold a substrate during performance of one or more processing operations, according to at least one embodiment.

FIG. 1B illustrates schematically in-plane and out-of-plane deformation of a substrate placed on a chuck, according to at least one embodiment.

FIG. 2 illustrates schematically example chuckability reference data for a sample 30 cm wafer, according to at least one embodiment.

FIG. 3 illustrates an example Zernike polynomial decomposition of one actual deformation (top left) of a substrate, in arbitrary units, into a paraboloid bow deformation (top right), a saddle deformation (bottom left), and a residual deformation, (bottom right), according to at least one embodiment.

FIGS. 4A-E illustrate schematically a process of correcting a substrate deformation using deposition of a stress-compensation layer (SCL) and an application of a stress-modulation beam applied to the SCL, in accordance with at least one embodiment.

FIGS. 5A-5B illustrate an example chuckability analysis performed for a sample substrate, according to at least one embodiment.

FIGS. 6A-6B illustrate an example reduction in the amplitude of the harmonics of FIGS. 4A-4B using a scale-modulated stress-modulation beam, according to at least one embodiment.

FIGS. 7A-7C illustrate a capacitance model that can be used to relate settings of an electrostatic chuck to the clamping pressure of electrostatic forces exerted on a substate held by the electrostatic chuck, according to at least one embodiment.

FIG. 8 is a flowchart illustrating an example method of improving chucking of substrates using stress-compensation beams with multiscale irradiation doses, according to at least one embodiment.

FIG. 9 is a flowchart illustrating an example method of determining settings for beam irradiation, according to at least one embodiment.

FIG. 10A-10B illustrate schematically an irradiation system capable of performing irradiation of stress compensation layers, according to at least one embodiment.

FIG. 11 depicts a block diagram of an example computer system capable of supporting operations of the present disclosure, according to at least one embodiment.

### DETAILED DESCRIPTION

Modern technology often aims to maximize chip area utilization by manufacturing complex three-dimensional devices with vertical stacks of many layers of semiconductor structures. For example, in NAND flash memory devices, lateral relative arrangement (CMOS near Array, or CnA) of memory cells (e.g., floating gate transistors) and peripheral transistors (e.g., CMOS circuitry used to support write/read operations with memory cells) has mostly given way to a vertical arrangement (CMOS under Array, or CuA) in which peripheral CMOS circuitry is disposed under an array of memory cells. In some instances, stacks of layers of memory cells can be manufactured on top of other stacks creating a structure in which precise alignment of various features within the layers is important for proper functioning of the manufactured devices. In one example, a stack of multiple (e.g., tens, hundreds, or more) alternating oxide (O) and nitride (N) layers (e.g., silicon oxide and silicon nitride layers, in one example) can be deposited on top of a substrate, e.g., silicon wafer. Various other layers/films can be deposited on wafers, e.g., polycrystalline silicon layers, carbon and polymer protective films, and/or the like. In another example of a three-dimensional (3D) Dynamic Random-Access Memory (DRAM) manufacturing, a stack of alternating Si₁₋ₓGeₓ (SiGe) alloy layers and silicon (e.g., epitaxial silicon) layers can be deposited on top of a silicon substrate.

Precise alignment (vertical and horizontal) of various features formed on substrates is important for adherence of manufactured devices to technical specifications. On the other hand, features formed on substrates are typically non-uniform and have complex patterns made of different materials. This results in stresses applied to substrates and the ensuing in-plane and out-of-plane deformation. Substrate deformation can cause misalignment of manufactured features and lead to suboptimal or even non-functioning devices. During manufacturing operations (e.g., deposition, etching, particle irradiation, cleaning, and/or the like) substrates are typically held in place using specially designed plates—chucks—that exert vacuum suction forces (in case of vacuum chucks) or electric forces (in case of electrostatic chucks, or ESCs) on the substrates. High-precision feature manufacturing requires secure attachment of substrates to chucks for accurate positioning and temperature control. While forces exerted by chucks on substrates can flatten moderately-deformed substrates, more substantial deformations can impact the ability of chucks to deliver expected performance, e.g., to securely hold substrates in a way that facilitates correct placement and proper alignment of features formed thereon—the functionality referred to as chuckability herein. Factors detrimentally affecting chuckability include substrate warpage, substrate surface roughness, non-uniformity of substrates and features and films deposited thereon (including both the front side and back side of substrates), and/or the like. Sole reliance on forces applied by chucks to flatten strongly warped substrates can result in dielectric breakdown (in electrostatic chucks), increased stresses from lateral (e.g., friction) forces, stress-caused non-uniformities, and/or the like.

Aspects and embodiments of the present disclosure address these and other challenges of the modern semiconductor manufacturing technology by providing for systems and techniques that improve chuckability of substrates. More specifically, prior to chucking, deformation of substrates can be corrected using such techniques as deposition of stress compensation layers (SCLs) or films and modulation of stresses in SCLs using stress-modulation irradiation (e.g., by beams of ions, electrons, and/or photons). For example, SCL can compensate for a uniform (bow-like) deformation of substrates whereas stress-modulation beams can further correct for saddle-shaped and other, residual, deformation by local mitigation of stresses in target areas. This eliminates or reduces reliance on excessively high chucking voltages (or suction forces). Such dual techniques offer additional benefits. Improving chuckability of substrates not only ensures their secure attachment to chucks but also reduces substrates' in-plane distortion. This improves substrate/feature uniformity and results in more consistent processing of substrates, improved device performance, and the increased yield while reducing the risk of dielectric or mechanical breakdown. Additionally, the disclosed techniques and systems reduce operational costs and optimize manufacturing efficiency by minimizing equipment modifications and/or the need for specialized chucking techniques.

The disclosed embodiments can be applied to improving chucking of any “wafer” or “substrate,” which refers to any material capable of supporting one or more films, masks, photoresists, layers, etc., that are deposited, formed, etched, or otherwise processed during a fabrication process. For example, a wafer surface on which processing can be performed includes materials such as silicon, silicon oxide, silicon nitride, strained silicon, silicon on insulator, carbon doped silicon oxides, amorphous silicon, doped silicon, germanium, gallium arsenide, glass, sapphire, plastic, and any other materials such as metals, metal nitrides, metal alloys, and other conductive materials, depending on the application. Wafers include, without limitation, semiconductor wafers. Wafers may be exposed to a pretreatment process to polish, etch, reduce, oxidize, hydroxylate, anneal, UV cure, e-beam cure and/or bake the substrate surface. In addition to film processing directly on the surface of the wafer itself, any of the film processing steps disclosed may also be performed on an underlayer formed on the wafer as disclosed in more detail below, and the term “wafer surface” is intended to include such underlayer as the context indicates. Thus, for example, where a film/layer or partial film/layer has been deposited onto a wafer surface, the exposed surface of the newly deposited film/layer becomes the wafer surface. In some embodiments, wafers have a thickness in the range of 0.25 mm to 1.5 mm, or in the range of 0.5 mm to 1.25 mm, in the range of 0.75 mm to 1.0 mm, or more. In some embodiments, wafers have a diameter of about 10 cm, 20 cm, 30 cm, or more.

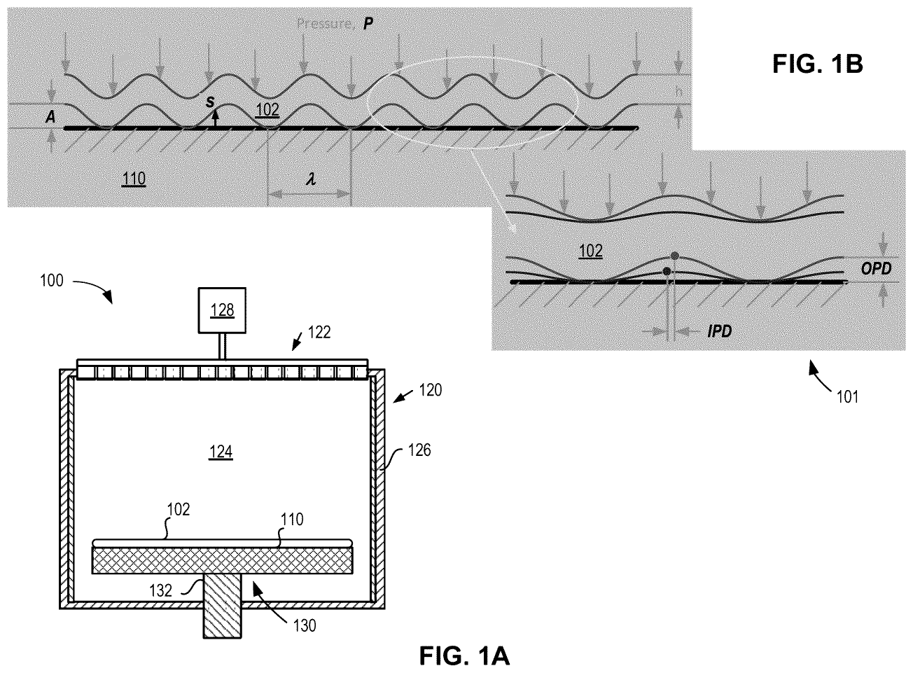

FIG. 1A illustrates an example sectional view of a processing chamber 100 capable of deploying a chuck 110 to hold a substrate 102 during performance of one or more processing operations, according to at least one embodiment. The processing chamber 100 can be a physical vapor deposition (PVD) chamber, a chemical vapor deposition (CVD) chamber, an atomic layer deposition (ALD) chamber, an etch chamber, an epitaxy chamber, a plasma chamber (e.g., a plasma etcher chamber, a plasma etch reactor chamber, a plasma cleaner chamber, etc.) and/or any other chamber of a device manufacturing system.

In one embodiment, the processing chamber 100 includes a chamber body 120, a showerhead 122, and walls 126 that enclose an interior volume 124. A gas source 128 can be coupled to the processing chamber 100 to provide process and/or cleaning gases to the interior volume 124 through the showerhead 122. A heater assembly 130 can be disposed in the interior volume 124 of the processing chamber 100, e.g., below the showerhead 122. The heater assembly 130 can include a chuck 110 that securely holds substrate 102 during processing. The chuck 110 can be attached to the end of a shaft 132 that is coupled to the chamber body 120 via a flange. The chuck 110 can further include mesas (e.g., dimples or bumps). The chuck 110 can additionally include electrodes and wires, for example, tungsten wires (not shown), embedded within the heater material of the chuck 110.

FIG. 1B illustrates schematically in-plane and out-of-plane deformation of a substrate placed on a chuck, according to at least one embodiment. As illustrated, substrate 102 is attracted to chuck 110 by application of a downward clamping pressure P, e.g., caused by electrostatic forces of attraction to chuck 110 (e.g., one or more electrodes built into the chuck). As illustrated, substrate 102 of thickness h has a single-harmonic deformation with wavelength 1 and amplitude A, such that the profile of deformation of substrate 102 has the form (the amount of deformation is exaggerated in FIG. 1B),

$$s ( x ) = \frac{A}{2} ( 1 + cos ( \frac{2 π x}{λ} ) ) ,$$

where s(x) stands for a gap between a surface of substrate 102 (e.g., the bottom surface) and a reference surface (e.g., the surface of chuck 110) as a function of a coordinate x along the substrate.

As illustrated with the blowout portion 101 in FIG. 1B, various points of substrate 102 experience both an in-plane deformation (IPD) and an out-of-plane deformation (OPD), which are related through the substrate curvature expressed in the s (x) dependence. OPD affects chuckability (with substrates having a large OPD having no or reduced chuckability) whereas IPD affects alignment of features deposited, formed, etched, or otherwise manufactured on substrate 102.

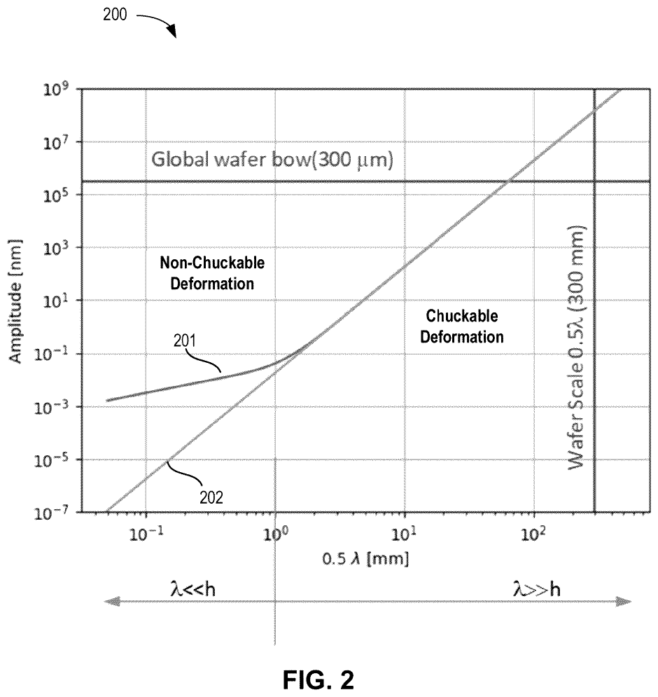

Chuckability can be modeled using a suitable elastic model of substrate deformation. FIG. 2 illustrates schematically example chuckability reference data 200 of a sample 30 cm wafer, according to at least one embodiment. Chuckability reference data 200, as illustrated, can include one or more chuckability curves. As illustrated, a first chuckability curve 201 is a fitting curve obtained using a finite-element method:

$${A}_{1} ( λ ) = \frac{P}{E} [ {a}_{1} λ + {b}_{2} \frac{{λ}^{4}}{{h}^{3}} ( 1 - {c}_{2} \frac{{h}^{2}}{{λ}^{2}} ) ] ,$$

where P is the applied clamping pressure, E is the Young's modulus of the material, and a₁, b₁, and c₁ are suitably chosen fitting parameters that depend on the size and material of the substrate (see, e.g., Turner, Ramkhalawon, and Sinha, Role of wafer geometry in wafer chucking, Journal of Micro/Nanolithography, Microfabrication, and Microsystems, Volume 12, id. 023007 (2013)). A second chuckability curve 202 is a curve obtained using the Timoshenko shear-corrected beam theory model:

$${A}_{2} ( λ ) = \frac{P {λ}^{4}}{{Eh}^{3}} [ {a}_{2} + {b}_{2} \frac{{h}^{2}}{{λ}^{2}} ] ,$$

where a₂ and b₂ are known functions of the Poisson ratio of the substrate material (see the above-referenced Turner et al., 2013). Deformations characterized by amplitudes A that are below the respective curves in the plane λ-A, namely, A<Aⱼ(λ), are predicted to be chuckable, meaning that the substrate can be substantially flattened (e.g., up to a certain tolerance amplitude) by the applied pressure P (P=80 kPa in FIG. 2) while deformations characterized by amplitudes A that are above the respective curves, A>Aⱼ(1) are not chuckable. Whereas both models yield the same chuckability curves A₁(λ)≈A₂(λ) for λ>4 mm, the two models predict substantially different maximum amplitudes for smaller wavelengths. (The finite-element chuckability curve 201 is expected to be more accurate at such wavelengths.) The form of the curves indicates that smaller wavelength deformations are more difficult to chuck than the larger wavelengths. Because the equations of the elastic theory of plates are linear, chuckability of different wavelengths can be modeled independently.

To determine where a deformation of a given substrate is relative to a chuckability curve (e.g., finite-element chuckability curve 201), the substrate can undergo a measurement of its height profile s(\vec{r}), where \vec{r} stands for the Cartesian coordinates x, y, polar coordinates r, φ or some other suitable set of coordinates (e.g., elliptic coordinates). The profile s(\vec{r}) can refer to the vertical coordinate of the bottom surface of substrate 102 (with reference to FIG. 1B), the top surface of substrate 102 or to some other reference surface. In some embodiments, height profile s(\vec{r}) of substrate 102 can be measured using optical metrology (e.g., optical interferometry) techniques. In some embodiments, the height profile s(\vec{r}) can be measured after one or more features are deposited on substrate 102.

The height profile s(\vec{r}) can then be represented via a number of parameters that qualitatively and quantitatively characterize geometry of the wafer deformation, e.g., a set of Zernike (or a similar set of) polynomials, s(\vec{r})=ΣⱼAⱼZⱼ(\vec{r}), a set of Fourier harmonics, or a combination of Zernike polynomials and Fourier harmonics. Consecutive coefficients A₁, A₂, A₃, A₄ . . . represent weights of specific geometric features (elemental deformations) of substrate 102 described by the corresponding Zernike polynomials Z₁(r, φ), Z₂(r, φ), Z₃(r, φ), Z₄(r, φ) . . . . (Herein, the Noll indexing scheme for the Zernike polynomials is being referenced.)

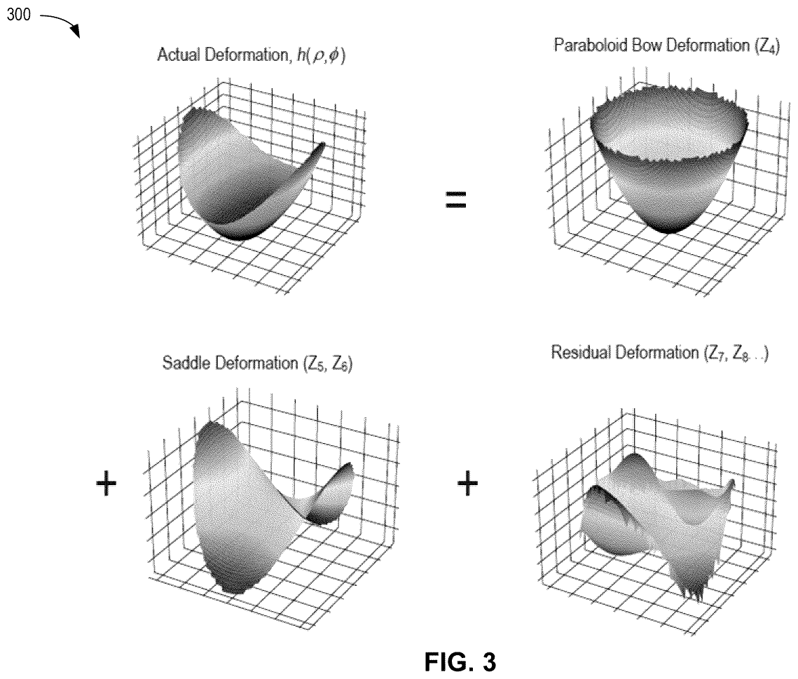

FIG. 3 illustrates an example Zernike polynomial decomposition 300 of one actual deformation s(r, φ) (top left) of a substrate (e.g., substrate 102), in arbitrary units, into a paraboloid bow deformation A₄Z₄(r, φ) (top right), a saddle deformation A₅Z₅(r, φ)+A₆Z₆(r, φ) (bottom left), and a residual deformation, sᵣₑₛ(r, φ) (bottom right), according to at least one embodiment.

The first three coefficients are of less interest as they describe a uniform shift of substrate 102 (coefficient A₁, associated with the Z₁(r, φ)=1 polynomial), a deformation-free x-tilt that amounts to a rotation around the y-axis (coefficient A₂, associated with the Z₂(r, φ)=2r cos φ polynomial), and a deformation-free x-tilt that amounts to a rotation around the x-axis (coefficient A₃, associated with the Z₃(r, φ)=2r sin φ polynomial) that can be eliminated by a realignment of the coordinate axes. The fourth coefficient A₄ is associated with Z₄(r, φ)=\sqrt{3}(2r²−1) and characterizes an isotropic paraboloid deformation (“bow”). The fifth A₅ and the sixth A₆ coefficients are associated with Z₅(r, φ)=\sqrt{6}r² sin 2φ and Z₆(r, φ)=\sqrt{6}r² cos 2φ polynomials, respectively, and characterize a saddle-type deformation. The A₅ coefficient characterizes a saddle shape that curves up (A₅>0) or down (A₅<0) along the diagonal y=x and curves down (A₅>0) or up (A₅<0) along the diagonal y=−x. The A₆ coefficient characterizes a saddle shape that curves up (A₆>0) or down (A₆<0) along the x-axis and curves down (A₆>0) or up (A₆<0) along the y-axis. The higher coefficients A₇, A₈, etc., characterize progressively faster variations of the wafer deformation s(r, φ) along the radial direction, along the azimuthal direction, or both and collectively represent a residual deformation,

$${s}_{res} ( r , ϕ ) = s ( r , ϕ ) - {\sum }_{j = 4}^{6} {A}_{j} {Z}_{j} ( r , ϕ ) .$$

Optical inspection followed by Zernike polynomial decomposition determines the parabolic (uniform or global) bow deformation A₄. Parabolic bow deformation can be eliminated by deposition of a stress compensation layer (SCL) on substrate 102. The remaining non-parabolic deformation can then be corrected by application of a stress-modulation beam with local (position-dependent) doses of stress-modulation particles.

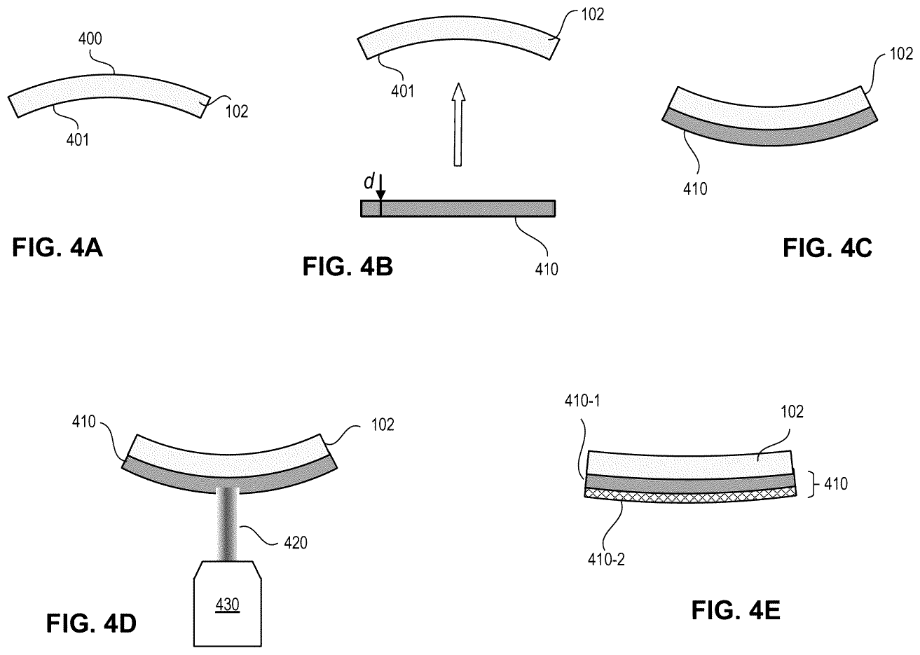

FIGS. 4A-E illustrate schematically a process of correcting a substrate deformation using deposition of an SCL and an application of a stress-modulation beam applied to the SCL, according to at least one embodiment. FIG. 4A depicts substrate 102 having a deformation, which can include a paraboloid bow deformation (with negative coefficient A₄<0, as illustrated) and can further include other deformations, including saddle deformation, residual deformation, etc. The wafer's front side 400 can include any number of features, e.g., deposition and/or etching patterns, a stack of layers/films, and/or any other structures. FIG. 4B illustrates deposition of an SCL 410 on the back side 401 of substrate 102. SCL 410 can be (or include) a silicon nitride layer or some other type of material. In some embodiments, SCL 410 can include layers of multiple materials. In some embodiments, a material of SCL 410 can be selected in view of the sign of coefficient A₄. For example, for a negative bow, A₄<0, SCL 410 can be selected to have a compressive stress (as illustrated in FIGS. 4B-4E). Conversely, for a positive bow, A₄>0, SCL 410 can be selected to have a tensile stress. SCL 410 can be deposited using any suitable deposition techniques including physical vapor deposition (e.g., sputtering), chemical vapor deposition (e.g., plasma-assisted deposition), epitaxy, exfoliation, and/or the like. SCL 410 can be deposited using any suitable deposition techniques including physical vapor deposition (e.g., sputtering), chemical vapor deposition (e.g., plasma-assisted deposition), epitaxy, exfoliation, and/or the like. Deposition can be performed at room temperature or at temperatures different from room temperature (e.g., at an elevated temperature). In some embodiments, thickness d of SCL 410 can be selected to overcorrect the wafer deformation to some degree, e.g., as illustrated in FIG. 4C where a positive paraboloid is overcorrected to a negative paraboloid bow. The thickness-dependent paraboloid bow correction A_{corr}(d) changes wafer deformation from s(r, φ) to s_{corr}(r, φ):

$${s}_{corr} ( r , ϕ ) = s ( r , ϕ ) + {A}_{corr} ( d ) \cdot {Z}_{4} ( r , ϕ ) .$$

The degree of overcorrection can be chosen in conjunction with a type and parameters (e.g., energy, dose, etc.) of a specific stress-modulation beam 420 to be used on SCL 410. The overcorrection can make the combined structure of substrate 102 and SCL 410 susceptible to further control of stress (and thus control of deformation of the wafer h_{corr}(r, φ)). As illustrated in FIG. 4D, collimating and focusing column 430 can generate a stress-modulation beam 420 that strikes SCL 410 and changes its elastic properties, e.g., by creating vacancies, breaking crystal bonds, depositing ions, and/or via any other applicable mechanisms. Stress-modulation beam 420 can carry photons, electrons, silicon ions, phosphorus ions, argon ions, neon ions, xenon ions, krypton ions, and/or the like. In some embodiments, the energy and type of ions in stress-modulation beam 420 can be selected to limit the implanted ions to the volume of SCL 410 without allowing the ions to reach substrate 102 (and/or any layers/films deposited on substrate 102). Ions that lodge in SCL 410 create substitution defects therein. Additionally, the ions leave a trail of vacancy defects along paths of propagation in SCL 410. The substitution defects and/or vacancies mitigate (e.g., reduce) stress in SCL 410 and can reduce the degree of stress overcorrection caused by the SCL deposition. This causes the combination of substrate 102 and SCL 410 to flatten.

In some embodiments, the number of ions ΔNᵢ deposited per small area ΔA=ΔxΔy (or the total amount of photon energy applied to this area) of substrate 102 can be determined using simulations (performed as described in more detail below) based on the local value of the corrected deformation S_{corr}(r, φ), which may include a saddle deformation, a residual deformation, and the part of the paraboloid bow deformation A_{corr}(d)+A₄ that has been overcorrected by the deposition of stress-compensation layer 420. The target local density n(x, y)=ΔNᵢ/ΔxΔy of the ions can be delivered by controlling the scanning velocity v of stress-modulation beam 420. In some embodiments, stress-modulation beam 420 has a profile that can be approximated with a Gaussian function, e.g., the ion flux j(ρ)=j₀ exp (−x²/a²−y²/b²), where x and y are Cartesian coordinates, j₀ is the maximum ion flux at the center of the beam, and a and b is are characteristic spreads of the beam along the x-axis and y-axis, respectively. Correspondingly, a point that is located at distance y from the path of the center of the beam receives an ion dose that includes the following number of ions:

$$\frac{Δ {N}_{i}}{Δ x Δ y} = \frac{{j}_{0}}{v} {\int }_{- ∞}^{∞} dx {e}^{- {x}^{2} / {a}^{2} - {y}^{2} / {b}^{2}} = \frac{{j}_{0} \sqrt{π}}{va} {e}^{- {y}^{2} / {b}^{2}} .$$

Correspondingly, by reducing the scanning velocity v, the number of ions received by various regions of SCL 410 can be increased, and vice versa. Additionally, stress-modulation beam 420 can perform multiple scans with different offsets y so that various points of SCL 410 receive multiple doses of ions with different factors e^{-y}^{²}^{/b}^{²} that can average to a target dose. For example, after n passes of stress-modulation beam 420, each made with a respective velocity vₖ at a different distance yₖ from the center of the beam to the area ΔxΔy, the total dose of ions (or amount of electromagnetic radiation) received by this area will be

$$n ( x , y ) = \frac{Δ {N}_{i}}{Δ x Δ y} {\vert}_{total} = {j}_{0} \sqrt{π} {\sum }_{k = 1}^{n} \frac{{e}^{- {y}_{k}^{2} / {b}^{2}}}{{av}_{k}} .$$

As illustrated in FIG. 4E, presence of a stress-mitigated portion 410-2 of SCL 410 results in a significant mitigation of deformation of substrate 102, including saddle and residual deformations (the remaining portion 410-1 of SCL 410 may be unmitigated or weakly mitigated and may include deeper regions o SCL 410 with little exposure to stress-modulation beam 420).

In some embodiments, the intensity and/or total amount of irradiation per various areas of substrate 102 can be determined using simulations, e.g., Monte Carlo simulations. The Monte Carlo simulations can be performed for a film made of the actual material used in SCL deposition and having a specific thickness d. An initial Monte Carlo simulation can be performed for specific baseline (default) conditions of the particle irradiation (e.g., default settings of an ion implantation apparatus). The baseline conditions can include a default type of particles, a default energy of the particles, a default dose of particles to be applied to SCL 410 (e.g., a default velocity of scanning and a default scanning pattern), and the like. The baseline conditions can subsequently be modified (e.g., optimized) using the Monte Carlo simulations. The Monte Carlo simulations can use calibration data collected (measured) for actual particle irradiation performed for various ion/photon/electron energies, types of ions, types and materials of masks/layers, angles of particle incidence on the films, and/or the like.

In some embodiments, the implantation map n(\vec{r}) can be computed using an influence function G(\vec{r}; \vec{r}′) that characterizes a response (e.g., deformation) at a point \vec{r} of the wafer as caused by a point-like force applied at another point \vec{r}′ of substrate 102. In some embodiments, the influence function G(\vec{r}; \vec{r}′), also known as the Green's function, can be determined from computational simulations or from analytical calculations. In some embodiments, the influence function can be determined from one or more experiments, which can include performing ion implantation into a film deposited on a reference wafer.

In some embodiments, substrate deformation s(\vec{r})=s_{quad}(\vec{r})+sᵣₑₛ(\vec{r}) can be represented (decomposed) as a combination of a quadratic s_{quad}(\vec{r}) and residual (non-quadratic) sᵣₑₛ(\vec{r}) contributions. The quadratic deformation can include a parabolic (paraboloid) part, which has the complete axial symmetry, and a saddle part. The thickness d of SCL 410 can be computed (or empirically determined) in such a way that the mask is to apply a desired target stress to substrate 102. To eliminate a non-uniform saddle deformation, SCL 410 can be of such thickness/material that turns the saddle deformation into a cylindrical deformation having a definite sign throughout the area of substrate 102. The uniform-sign cylindrical deformation (as well as a residual higher-order non-quadratic deformation) can then be mitigated with irradiation by stress-modulation beam 420. In some embodiments, a cylindrical decomposition is not unique and can be either positive (upward-facing cylindrical deformation) or negative (downward-facing cylindrical deformation). Both decompositions can be analyzed and a decomposition that enables a more effective stress mitigation can be selected. For example, a decomposition that is characterized by a smaller parabolic bow deformation can be selected. The parabolic bow deformation can be mitigated using a choice of SCL 410 (e.g., type and thickness) while the remaining cylindrical deformation (and the higher-order residual deformation) can be addressed by appropriately selected ion or photon irradiation doses n(\vec{r}).

In some embodiments, mitigation of a cylindrical deformation or a saddle deformation can include identifying principal axes (directions) of the cylinder/saddle and a magnitude of the cylindric/saddle deformation and directing stress-modulation beam 420 into appropriately selected edge regions of SCL 410. For example, individual edge regions to which the stress-modulation beam 420 is directed can have a width that is at or below 30% of a diameter of substrate 102. Residual higher-order (ripple) deformations can then be mitigated with further irradiation into the area of SCL 410.

In some embodiments, determination of dose maps n(x, y) of stress-modulation particles can be performed using chuckability reference data 200, e.g., one of the chuckability curves 20x introduced in conjunction with FIG. 2. More specifically, the measured deformation profile s(x, y) of the substrate can be decomposed into a suitable set of harmonics or polynomials. In one example embodiment, the substrate deformation s(x, y) can be represented as a sum of the isotropic Z₄ parabolic bow deformation and anisotropic deformation,

$$s ( x , y ) = S ( x , y ) + {A}_{4} {Z}_{4} ( x , y ) ,$$

with the anisotropic portion expanded in the Fourier series, e.g.,

$$S ( x , y ) = {\sum }_{j = 0}^{N - 1} {\sum }_{k = 0}^{N - 1} S ( j , k ) exp ( \frac{2 π i}{N} ( jx + ky ) ) ,$$

with a suitable number N of points. Various Fourier coefficients, also referred to as harmonics herein, S(j, k) (e.g., absolute values of those, in general, complex components) can then be compared with the chuckability data.

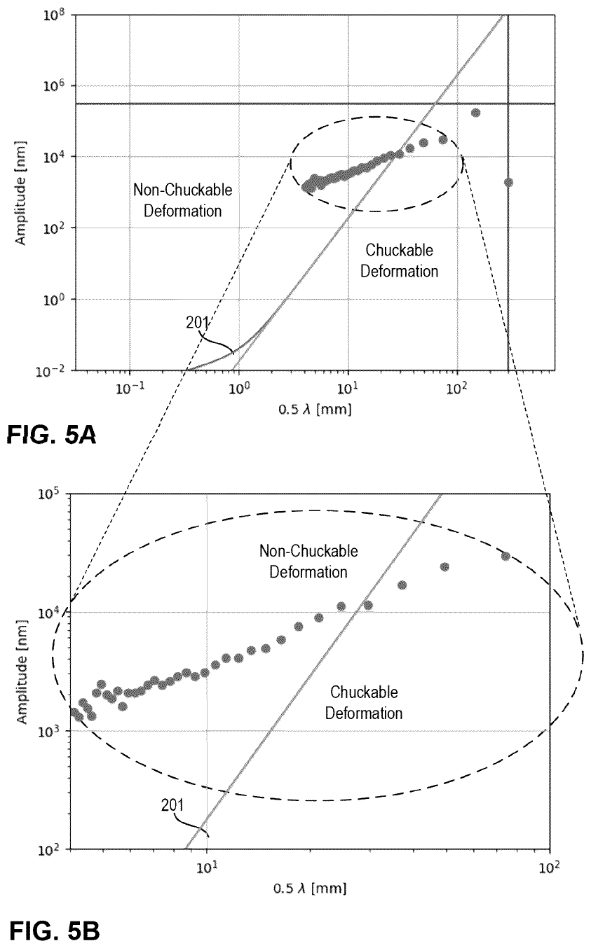

FIGS. 5A-5B illustrate an example chuckability analysis performed for a sample substrate, in accordance with at least one embodiment. FIG. 5A illustrates the chuckability curve 201 and a set of Fourier harmonics S(j, k), whose amplitude is indicated with dots on a log-log plot. The wavelength of different harmonics is λ(j, k)=L/\sqrt{j²+k²}, where L is the size of the region (e.g., square) for which the Fourier transform is computed, e.g., L=30 cm, the diameter of the substrate. FIG. 5B shows a close-up view of the central region of FIG. 5A. As illustrated, the first n (e.g., n=6 in this example) harmonics S(j, k) are correctable (“chuckable”) upon application of the set clamping pressure P for which the chuckability curve 201 is computed. Specifications of a particular processing operation can tolerate sufficiently low wavelengths A (j, k) that amount to fast and less detrimental deformations of the substrate. For example, a given processing operation can tolerate harmonics with a wavelength that is smaller than the wavelength of the first m target harmonics. In those instances where m>n, settings of the stress mitigation beam 420 to be applied to the SCL 410 deposited on the substrate 120 (with reference to FIGS. 4A-4E) can be determined to mitigate the remaining m-n harmonics of the more important first m harmonics. Mitigation of these harmonics using the stress-modulation beam can reduce the corresponding amplitudes S(j, k) and move them from the region of non-chuckable deformation to the region of chuckable deformation (with reference to FIG. 2).

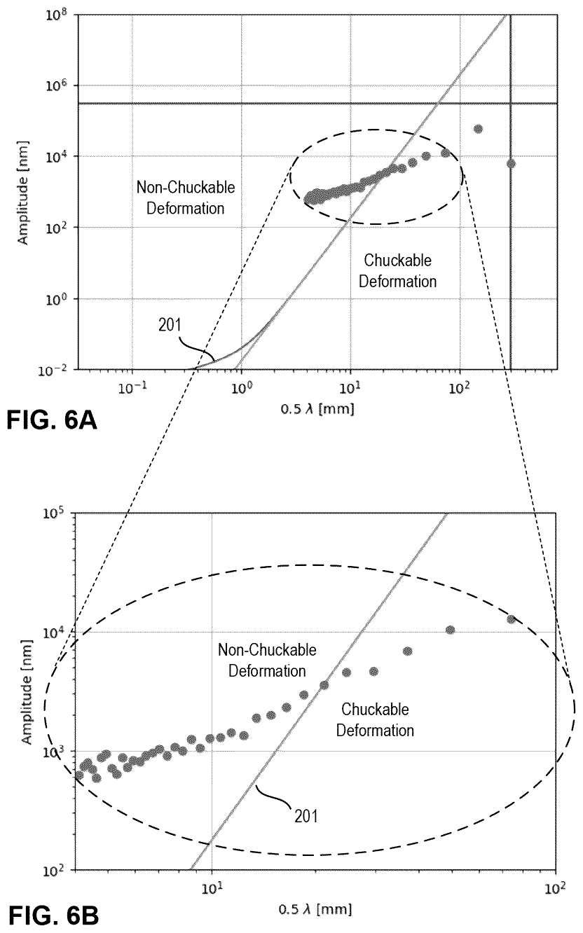

In some embodiments, mitigation of the target harmonics can be performed by selecting dose maps n(x, y) that are similar, e.g., proportional, to the deformation associated with these target harmonics,

$$n ( x , y ) = C {\sum }_{j , k ∈ TH} S ( j , k ) exp ( \frac{2 π i}{N} ( jx + ky ) ) ,$$

where the sum is extended over the set TH of the m target harmonics and C is a constant factor that can be determined empirically. In some embodiments, the sum can be extended over those m−n target harmonics that were determined to be initially in the region of non-chuckable deformation whereas n target harmonics that were determined to be in the region of chuckable deformation are not used in computation of the dose maps n(x, y). In some embodiments, the dose maps n(x, y) can be determined using simulations, e.g., Monte Carlo simulation (as described above), Green's functions, solving elastic plate equations using the finite-element method, and/or the like. The dose maps n(x, y) are then determined from the condition that the mitigation of stresses, caused by these dose maps n(x, y), results in moving at least the m-n target harmonics into the region of chuckable deformation, as illustrated with FIGS. 6A-6B.

FIGS. 6A-6B illustrate an example reduction in the amplitude of the harmonics of FIGS. 5A-5B using a scale-modulated stress-modulation beam, in accordance with at least one embodiment. As illustrated, the application of a stress-modulation beams has resulted in the m−n=2 additional harmonics moving into the region of the chuckable deformation. Although the example case of m=8 and n=6 is illustrated in FIGS. 5A-5B and FIGS. 6A-6B, any number of harmonics can be corrected by similar techniques.

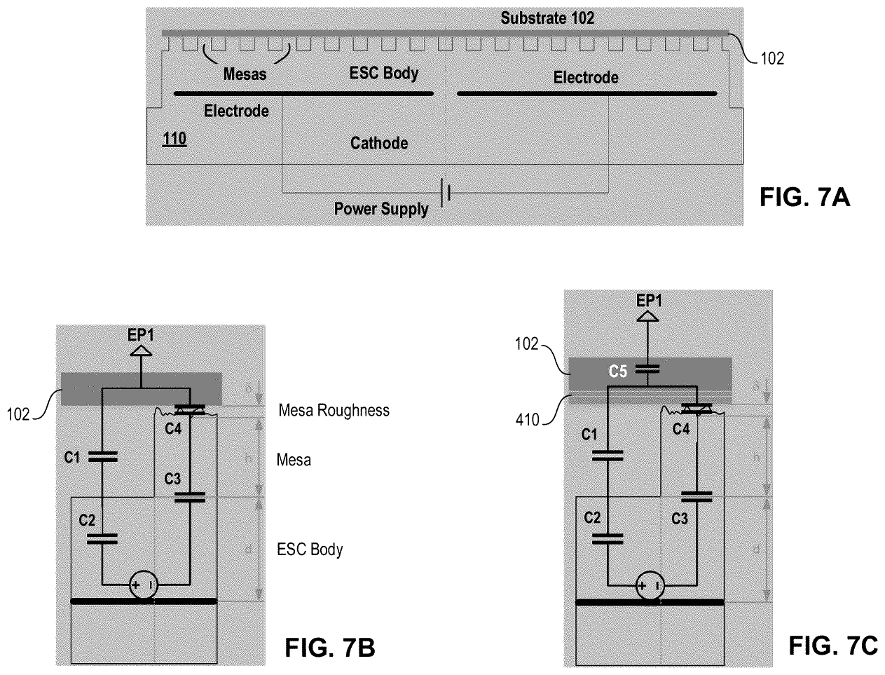

FIGS. 7A-7C illustrate a capacitance model that can be used to relate settings of an electrostatic chuck to the clamping pressure of electrostatic forces exerted on a substate held by the electrostatic chuck, in accordance with at least one embodiment. As illustrated in FIG. 7A, a chuck 110, which can be an ESC (e.g., a Coulombic chuck, a Johnsen-Rahbek chuck, and/or the like), can have a set of protruding mesas (bumps) spaced several millimeters or one or more centimeters apart designed to prevent particle contaminants from being trapped under substrate 102 during the clamping process (and thus cause additional deformation of substrate 102). Chuck 110 can include one or more electrodes to which a set of external potentials can be delivered using one or more suitable power supply devices, e.g., a dc power supply, in some embodiments. As illustrated in FIG. 7B, clamping pressure P can be computed by determining electric fields acting within the chuck-substrate system. More specifically, a spacing between mesas can be modeled with a first capacitance C₁ (which can be determined based on the height and distance between mesas and/or modeled by solving electrostatics equations), the ESC body can be modeled with a second capacitance C₂, the combination of the mesas and the ESC body (in the location of the mesas) can be modeled with a third capacitance C₃, and surface roughness of the mesas can be modeled with a fourth capacitance C₄. In those instances where the substrate 102 has one or more films (e.g., SCL 410, oxide protective layers, etc.) deposited on a back side (or front side) of substrate 102, as illustrated in FIG. 7C, an additional fifth capacitance C₅ can be used to model these films. The charges on various capacitances C₁-C₄ (or C₁-C₅) can then be used to determine the force, and hence clamping pressure P acting on substrate 102. The clamping pressure can be used in computations of various chuckability curves (e.g., the chuckability curve 201, chuckability curve 202, and/or the like, with reference to FIGS. 2, 5, and 6).

The capacitance model of FIGS. 7A-7C can be used with Coulombic ESCs, e.g., aluminum oxide chucks. For applications to Johnsen-Rahbek chucks, e.g., aluminum nitride chucks, which allow leakage currents to flow through the ESC body (and mesas), the capacitance model of FIGS. 7A-7C can be augmented with resistances that are connected in parallel to capacitances C₃ and C₄ (and C₅, if applicable). In some embodiments, Johnsen-Rahbek chucks can also be modeled without the resistances (e.g., under the assumption that the leakage currents are negligibly small).

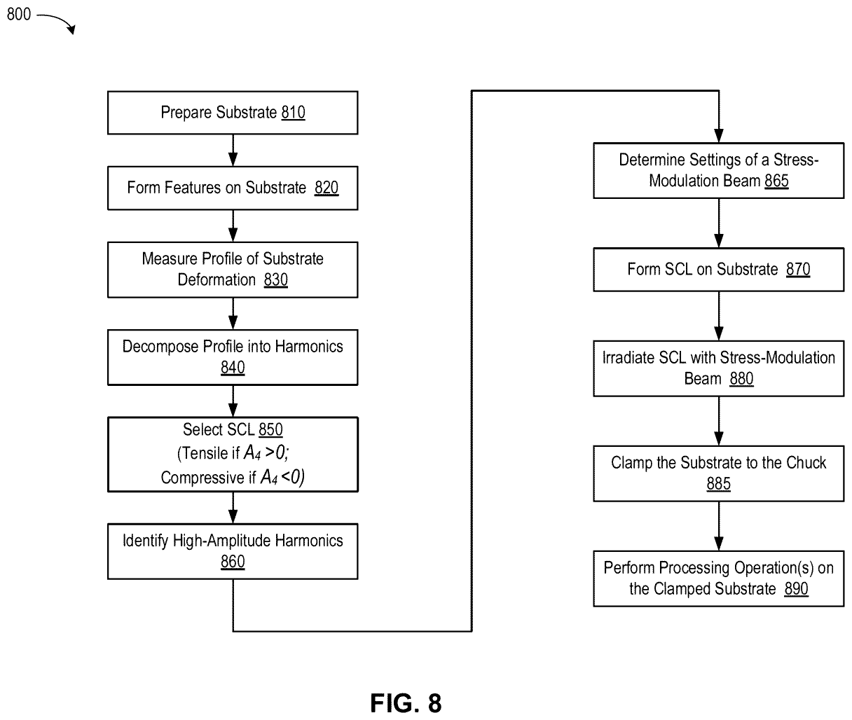

FIG. 8 is a flowchart illustrating an example method 800 of improving chucking of substrates using stress-compensation beams with multiscale irradiation doses, in accordance with at least one embodiment. Method 800 can be performed using a semiconductor manufacturing system that includes one or more processing chambers, e.g., deposition chamber(s), plasma chamber(s), etching chamber(s), polishing chamber(s), film removal chamber(s), beam irradiation chamber(s), optical inspection chamber(s), and/or the like. The processing chambers can be connected to one or more transfer chambers, which can be equipped with robot(s) to handle substrates, e.g., moving substrates into and out of processing chambers. The transfer chamber can further be connected to a load-lock chamber (Front-End Interface) that can be coupled to one or more Front Opening Unified Pod carriers that hold bare substrates, processed substrates, partially processed substrates, and/or the like. Operations performed by the semiconductor manufacturing system, including any, some or all operations of method 800, can be performed responsive to instructions issued by a suitable computing device having a processing logic and memory to store the instructions.

At block 810, method 800 can include preparing a substrate, including but not limited to obtaining a bare substrate, preprocessing the bare substrate, e.g., polishing the substrate, removing stains and/or residue from the substrate, and/or the like, and/or performing any number of similar operations. At block 820, method 800 can continue with forming one or more features on the substrate. The features can include any number of patterns, layers, films, slits, masks, holes, and/or the like. For example, the features can include a layer of a conducting material, which can include interconnect circuitry, transistor, and/or the like. In some embodiments, the features can include oxygen layers, nitrogen layers, silicon layers, germanium layers, silicon-germanium alloy layers, and/or any other suitable layers. Various layers can be used as hosts of memory cells, transistors, separations between memory cells/transistors, and/or the like. In some embodiments, the features can include various protection layers deposited, or otherwise formed, to cover other features previously formed on the substrate.

At block 830, method 800 includes performing an optical inspection to obtain a profile of the deformation of the substrate, e.g., displacement of a surface (e.g., the bottom surface) of the substrate as a function of some suitable in-plane coordinates, e.g., polar coordinates z=s(r, φ), Cartesian coordinates, z=s(x, y), or some other coordinates. At block 840, method 800 includes decomposing the profile of the deformation of the substrate into a plurality of harmonics, e.g., Fourier harmonics, Zernike polynomials, and/or a combination thereof. For example, the profile of the deformation can be decomposed into a parabolic bow Zernike polynomial Z₄(r, φ) and the saddle Zernike polynomials Z₅(r, φ) and Z₆(r, φ) with the rest of the profile (residual, S (x, y)) expanded over Fourier harmonics (e.g., over Cartesian coordinates), s(r, φ)=A₄Z₄(r, φ)+A₅Z₅(r, φ)+A₆Z₆(r, φ)+S(x, y).

In some embodiments, method 800 can include a decision-making block 850 to select a type of SCL to be used with the substrate. For example, a decision at block 850 can be made based on the coefficient that determines a degree of parabolicity of the deformation, e.g., coefficient A₄. If the substrate is curved downwards (towards the back side of the substrate), A₄<0, a compressive SCL can be selected for the back side deposition at block 850. If A₄>0, a tensile SCL can be selected for back side deposition. Operations of block 850 can include determining a type of a material for the SCL to be deposited and a thickness d of the SCL. In some embodiments, this determination can be made based on multiple expansion coefficients (more than just the paraboloid bow coefficient A₄) from the set {Aⱼ} or the full profile h(r, φ). In one specific non-limiting example, the thickness d can selected based on a target paraboloid deformation Ã₄ sufficient to overcompensate for the measured substrate deformation.

At block 860, method 800 can include identifying, using chuckability reference data, one or more harmonics of the plurality of harmonics having an amplitude above a maximum amplitude capable of being flattened by a predetermined clamping pressure exerted on the substrate by a chuck (e.g., as disclosed in conjunction with FIGS. 4A-4B and FIGS. 5A-5B). For example, the chuckability reference data can identify, for an individual harmonic of the plurality of harmonics, the maximum amplitude of the individual harmonic capable of being flattened, to within a tolerance amplitude, by the predetermined clamping pressure.

At block 860, method 800 can include determining, based at least on a subset of the one or more harmonics, settings of a stress-modulation beam. In some embodiments, the subset of the one or more harmonics can include a harmonic associated with an isotropic bow deformation of the substrate and/or one or more harmonics associated with a saddle-shape deformation of the substrate. In some embodiments, the subset of the one or more harmonics can excludes short-wavelength harmonics of the plurality of harmonics, the short-wavelength harmonics having a wavelength below a threshold wavelength (λ<λ_{T}). In some embodiments, the stress-modulation beam can include a beam of ions, a beam of photons, and/or a beam of electrons, or some combination thereof. The settings for the stress-modulation beam can include a type of particles of the stress-modulation beam, an energy of the particles of the stress-modulation beam, and/or an angle of incidence of the particles of the stress-modulation beam.

At block 870, the SCL of the selected (at block 850) thickness d (or some fixed thickness) can be deposited (or otherwise formed) on the substrate (e.g., as illustrated in FIG. 4B). In some embodiments, the SCL can be (or include) a silicon nitride film. The SCL can cause a modification of deformation of the substrate. In some embodiments, the SCL modification can include a reduction of the deformation (but this is not a requirement). In some embodiments, as illustrated in FIG. 4C, the SCL can overcompensate the deformation of the substrate and change the overall sign of the deformation. Although shown after blocks 860 and 865 in FIG. 8, operations of block 870 can also be performed before these blocks, concurrently, or before block 830 with, e.g., measurements of the deformation performed after the SCL is formed.

In some embodiments, forming the SCL can be performed by a physical substrate deposition, chemical substrate deposition, atomic layer deposition, photoresist spin coating, optical lithography, imprint lithography, digital lithography, contact photolithography, proximity photolithography, projection photolithography, and/or other suitable techniques.

At block 880, method 800 can continue with irradiating the SCL (e.g., according to the computed irradiation doses) with a stress-modulation beam to reduce the amount of stress in the substrate and flatten the substrate (e.g., as illustrated in FIGS. 4D-4E).

At block 885, method 800 can include, after irradiating the SCL with the stress-modulation beam, using the chuck to clamp the substrate. In some embodiments, the chuck can be an electrostatic chuck, e.g., Coulombic chuck, a Johnsen-Rahbek chuck, and/or the like.

At block 890, method 800 can continue with performing one or more processing operations on the clamped substrate, e.g., deposition operation(s), etch operation(s), photomask placement and/or removal operation(s), cleaning operation(s), annealing operation(s), polishing operation(s), inspection operation(s), and/or the like or any combination thereof.

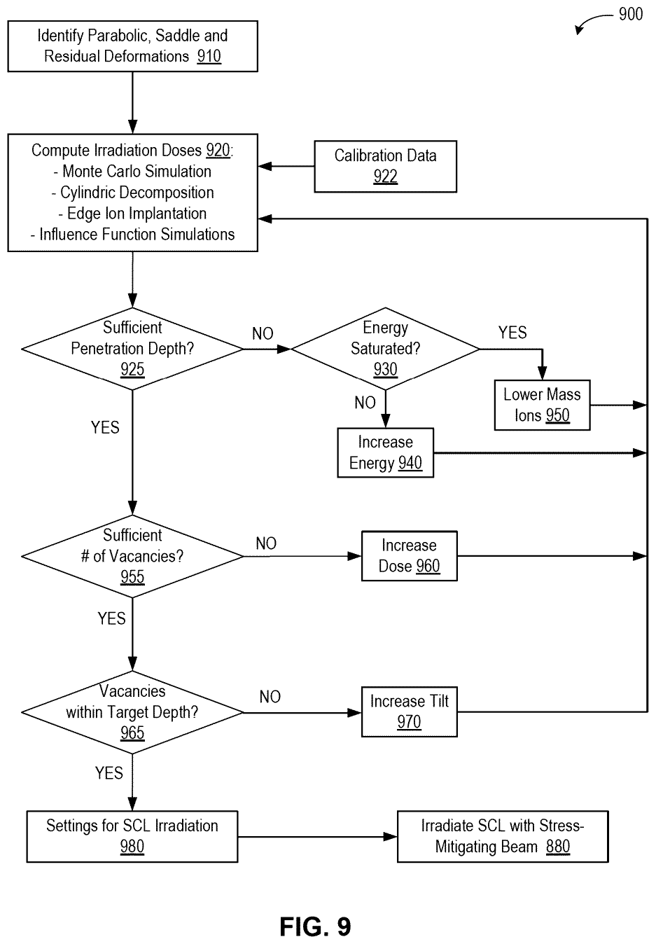

FIG. 9 is a flowchart illustrating an example method 900 of determining settings for beam irradiation, according to at least one embodiment. Method 900 can be performed as part of blocks 830-880 of method 800. At block 910, method 900 can include identifying some or all of a parabolic deformation (e.g., Zernike coefficients A₄), saddle deformation (e.g., Zernike coefficients A₅, A₆), and the residual deformation (e.g., Zernike coefficients A₇, A₈ . . . ) of a substrate, e.g., using profilometry measurements.

At block 920, method 900 can continue with computing irradiation doses n(\vec{r}) for the SCL deposited on the substrate. Operations of block 920 can include one or more techniques for determining n(\vec{r}). In some embodiments, irradiation doses n(\vec{r}) can be computed using Monte Carlo simulations. In some embodiments, irradiation doses n(\vec{r}) can be computed using cylindrical decomposition of s(\vec{r}), e.g., a decomposition of a saddle shape deformation into a parabolic deformation and a cylindrical deformation.

In some embodiments, irradiation doses n(\vec{r}) can be computed (and then applied at block 880) for selected edge regions of the SCL. For example, if the axis of cylindrical deformation is the y-axis, the edge regions can be regions located within some vicinity of points x=±R, y=0, where R is the radius of the substrate. Irradiation doses n(\vec{r}) near other regions (e.g., near the center of the substrate) can be significantly lower and/or zero, in some embodiments. In some embodiments, the edge regions of the SCL have a width that is at or below 30% of a diameter of the substrate. In some embodiments, the edge regions of the SCL can be exposed to a spatially uniform dose of particles of the stress-modulation beam, a radially-varying dose of particles of the stress-modulation beam, or an azimuthally-varying dose of particles of the stress-modulation beam. In some embodiments, irradiation doses n(\vec{r}) can be spread out more uniformly across the area of the substrate, e.g., can be non-zero both near the edges and near the middle of the substrate.

In some embodiments, irradiation doses n(\vec{r}) can be computed using an influence function G(\vec{r}; \vec{r}″), also known as the Green's function, which characterizes a response (e.g., deformation) of the substrate at a point \vec{r} of the substrate as caused by a point-like force applied at a point \vec{r}′ of the substrate. In some embodiments, the influence function G(\vec{r}; \vec{r}′) can be determined from computational simulations or analytical calculations. In some embodiments, the influence function can be determined from one or more experiments, which can include performing ion implantation into a film deposited on a reference substrate. In some embodiments, a combination of multiple techniques of determining the influence function G(\vec{r}; \vec{r}′) can be used.

As a way of example, the Monte Carlo simulations for a structure (e.g., substrate with films and an SCL deposited thereon) can be performed for specific materials of the structure (e.g., silicon substrate, stack of films, and/or the like) and for a specific thickness of the structure. An initial Monte Carlo simulation can be performed for baseline (default) conditions of beam irradiation (e.g., default settings of an ion implantation apparatus or a light-emitting apparatus). The baseline conditions can include a default type of particles (ions, photons, electrons), a default energy of particles, a default dose of particles to be directed to the SCL (e.g., a default velocity of scanning and a default scanning pattern), and the like.

In some embodiments, various techniques of irradiation dose computations can use calibration data 922 collected for actual irradiation performed for various types of the irradiation beams, energies of the irradiation beams, types and materials of structures being irradiated, angles of beam incidence on the structures, and/or the like. In some embodiments, calibration data 922 can be statistically preprocessed. For example, various measurements can be collected for multiple substrate/films/SCL materials, types of particles, angles of incidence, and/or other parameters. The statistically processed measurements can be stored (e.g., in a memory of a processing device performing computation of the irradiation doses) in the form of probability distributions of various quantities, including but not limited to:
distribution of the density of ion implantation with depth for different ion types, ion energies, angles of incidence;
distribution of the number of vacancies produced at different depths (per unit of length of travel of the ions) for different types of irradiation particles (ions, photons, electrons), particle energies, and angles of incidence;
distribution of stresses created by irradiation beams for different beam intensities and durations; and/or the like.

Performing irradiation dose computations of block 920 can include sampling from the stored distributions and identifying a likelihood that a target stress mitigation will be achieved with the default settings of conditions of beam irradiation of a SCL of a given type and thickness. Method 900 can include several verification operations designed to determine whether the target stress can be achieved without detrimentally affecting properties of the substrate/films. For example, at block 925, method 900 can include verifying if the penetration depth of the selected (e.g., default) type of particles is sufficient. For example, the penetration depth is to be at least a certain fraction of the thickness of the SCL, e.g., 20%, 30%, 50%, 80%, or more of that thickness. In some embodiments the penetration depth can be up to 100% of the thickness. If the energy is insufficient, method 900 can include checking, at block 930, if the irradiation beam source is capable of outputting particles of a higher energy. If higher energies are available, method 900 can continue with increasing the energy of the particles (block 940) and repeating irradiation dose computations of block 920 for the increased energy. If the maximum energy of the irradiation beam source has already been reached, method 900 can continue with replacing (at block 950) ions with ions of a different type (e.g., if an ion beam is used for irradiation), e.g., replacing Silicon ions with Boron, Carbon, Fluorine, etc., ions, and repeating Monte Carlo simulations for the ions of the new type.

At block 955, method 900 can include verifying whether the number of expected formed vacancies is sufficient. To verify sufficiency, method 900 can assess stress mitigation caused by formed vacancies. In one embodiment, method 900 can begin at some value of stress in the SCL, e.g., −3.0 GPa or some other suitable value (negative sign indicating compressive stress) and use beam irradiation to mitigate this stress towards a neutral point, 0.0 GPa at various locales of the SCL.

If the number of vacancies is insufficient, method 900 can include increasing a dose of particles (at block 960) and repeating irradiation dose computations of block 920 for the increased dose.

At block 965, method 900 can include verifying that the vacancies are going to be placed within a target depth, e.g., the thickness d of the film or a certain fraction of the film, such as 0.8 d, 0.7 d, 0.5 d, or some other value empirically set to prevent particles from penetrating into the substrate/films and affecting properties of the substrate/films. If the vacancies are to be formed at depths that exceed the target depth, method 900 can include (at block 970) increasing an angle of incidence (e.g., by tilting the irradiation beam) to keep vacancies (as well as substitution impurities) to a shallower region of the SCL.

Blocks 920-970 can be repeated multiple times until irradiation dose computations of block 920 are determined to be sufficient that the desired stress mitigation can be achieved, e.g., that the reduction in the tensile stress of the SCL is such that the deformation of the substrate is eliminated or at least reduced to an acceptable tolerance. The final settings for SCL irradiation (block 980) determined from irradiation dose computations can then be used for irradiation of the SCL with the stress-modulation beam (at block 880).

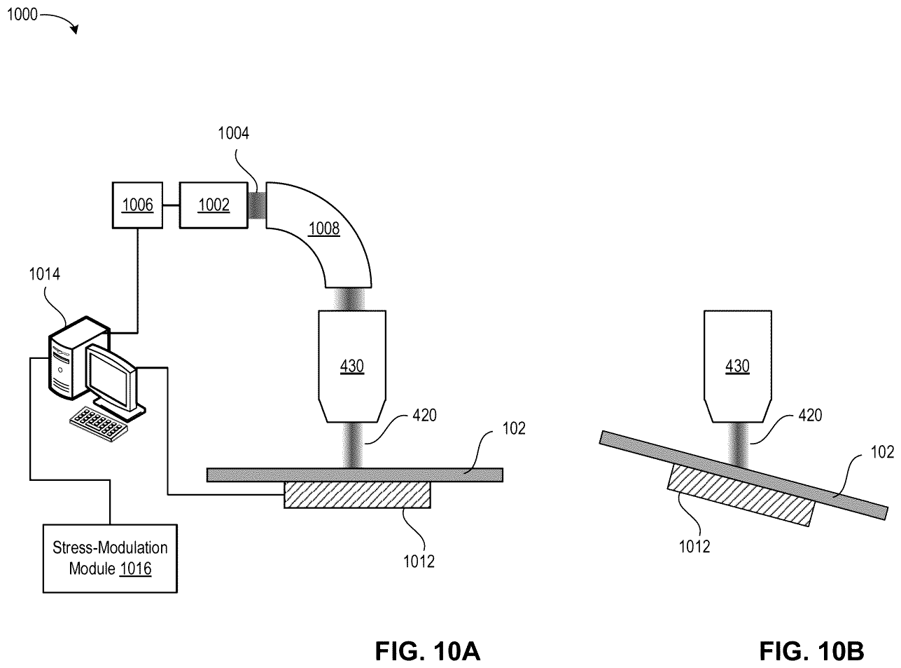

FIG. 10A illustrates schematically an irradiation system 1000 capable of performing irradiation of stress compensation layers, according to at least one embodiment. Irradiation system 1000 can include collimating and focusing column 430 of FIG. 1. Irradiation system 1000 can further include a beam source 1002 for producing a source beam 1004. Beam source 1002 can include a chamber for generating ions (e.g., a plasma chamber), a light source for generating photons (e.g., a laser, laser diode, lamp, etc.), a heated filament for producing electrons, and/or any other source for the particles of a type deployed in specific stress-modulation techniques of the instant disclosure. Beam source 1002 can be powered by a power element 1006 and can include an extraction electrode assembly (not shown). Irradiation system 1000 can include a mass spectrometer 1008 (e.g., in the instances where beam source 1002 produces charged particles, such as electrons or ions) and a collimating and focusing column 430. Collimating and focusing column 430 can direct stress-modulation beam 420 to substrate 102. Substrate 102 can be supported by a support stage 1012. In some embodiments, support stage 1012 and substrate 102 can remain stationary during irradiation of substrate 102 by stress-modulation beam 420 while components of irradiation system 1000 can be repositioned relative to substrate 102. In some embodiments, irradiation system 1000 can be stationary while support stage 1012 can reposition substrate 102. In some embodiments, stress-modulation beam 420 can have intensity (e.g., light intensity) that is modulated by changing intensity of beam source 1002 and/or placing a partially absorbing or partially reflecting material at some location between beam source 1002 and substrate 102. This enables delivery of local irradiation doses n(x, y) to various locations of substrate 102. Scanning with stress-modulation beam 420 can occur along multiple directions, e.g., along x-axis and along y-axis according to any suitable predetermined pattern, e.g., back- and forth along x-axis, in a spiral pattern, and so on. In various embodiments, stress-modulation beam 420 can be scanned with a frequency of several Hz, tens of Hz, hundreds of Hz, thousands of Hz, or more.

Operations of irradiation system 1000 can be controlled by a controller 1014, which can include any suitable computing device, microcontroller, or any other processing device having a processor, e.g., a central processing unit (CPU), a field-programmable gate array (FPGA), an application-specific integrated circuit (ASIC), and/or the like, and a memory device, e.g., a random-access memory (RAM), read-only memory (ROM), flash memory, and/or the like or any combination thereof. Controller 1014 can control operations of power element 1006, support stage 1012, and/or various other components and modules of irradiation system 1000. Controller 1014 can include a stress-modulation module 1016 capable of performing simulations that determine a target intensity of stress-modulation beam 420 to be used to mitigate various wafer deformations. In some embodiments, as illustrated in FIG. 10B, support stage 1012 can impart a tilt, e.g., in one or two spatial directions to substrate 102 to change an angle of incidence of stress-modulation beam 420 relative to substrate 102. In some embodiments, instead of tilting substrate 102, controller 1014 can cause a tilt of stress-modulation beam 420 relative to substrate 102.

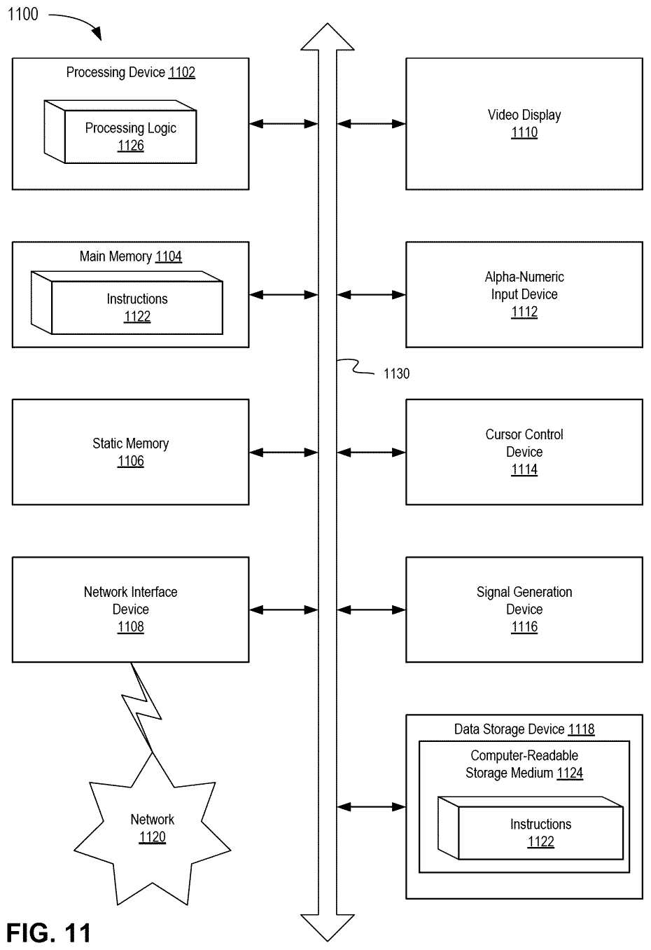

FIG. 11 depicts a block diagram of an example computer system 1100 capable of supporting operations of the present disclosure, according to at least one embodiment. In various illustrative examples, example computer system 1100 may be or include controller 1014 of FIG. 10A. Example computer system 1100 may be connected to other computer systems in a LAN, an intranet, an extranet, and/or the Internet. Computer system 1100 may operate in the capacity of a server in a client-server network environment. Computer system 1100 may be a personal computer (PC), a set-top box (STB), a server, a network router, switch or bridge, or any device capable of executing a set of instructions (sequential or otherwise) that specify actions to be taken by that device. Further, while only a single example computer system is illustrated, the term “computer” shall also be taken to include any collection of computers that individually or jointly execute a set (or multiple sets) of instructions to perform any one or more of the methods discussed herein.

Example computer system 1100 may include a processing device 1102 (also referred to as a processor or CPU), a main memory 1104 (e.g., read-only memory (ROM), flash memory, dynamic random access memory (DRAM) such as synchronous DRAM (SDRAM), etc.), a static memory 1106 (e.g., flash memory, static random access memory (SRAM), etc.), and a secondary memory (e.g., a data storage device 1118), which may communicate with each other via a bus 1130.

Processing device 1102 represents one or more general-purpose processing devices such as a microprocessor, central processing unit, or the like. More particularly, processing device 1102 may be a complex instruction set computing (CISC) microprocessor, reduced instruction set computing (RISC) microprocessor, very long instruction word (VLIW) microprocessor, processor implementing other instruction sets, or processors implementing a combination of instruction sets. Processing device 1102 may also be one or more special-purpose processing devices such as an application specific integrated circuit (ASIC), a field programmable gate array (FPGA), a digital signal processor (DSP), network processor, or the like. In accordance with one or more aspects of the present disclosure, processing device 1102 may include a processing logic 1126 configured to execute instructions (e.g., instructions 1122) implementing example method 800 of improving chucking of substrates using stress-compensation beams with multiscale irradiation doses, in accordance with at least one embodiment.

Example computer system 1100 may further comprise a network interface device 1108, which may be communicatively coupled to a network 1120. Example computer system 1100 may further comprise a video display 1110 (e.g., a liquid crystal display (LCD), a touch screen, or a cathode ray tube (CRT)), an alphanumeric input device 1112 (e.g., a keyboard), a cursor control device 1114 (e.g., a mouse), and an acoustic signal generation device 1116 (e.g., a speaker).

Data storage device 1118 may include a computer-readable storage medium (or, more specifically, a non-transitory computer-readable storage medium) 1124 on which is stored one or more sets of executable instructions 1122. In accordance with one or more aspects of the present disclosure, executable instructions 1122 may comprise executable instructions implementing example method 800 of improving chucking of substrates using stress-compensation beams with multiscale irradiation doses, in accordance with at least one embodiment.

Executable instructions 1122 may also reside, completely or at least partially, within main memory 1104 and/or within processing device 1102 during execution thereof by example computer system 1100, main memory 1104 and processing device 1102 also constituting computer-readable storage media. Executable instructions 1122 may further be transmitted or received over a network via network interface device 1108.

While the computer-readable storage medium 1124 is shown in FIG. 11 as a single medium, the term “computer-readable storage medium” should be taken to include a single medium or multiple media (e.g., a centralized or distributed database, and/or associated caches and servers) that store the one or more sets of operating instructions. The term “computer-readable storage medium” shall also be taken to include any medium that is capable of storing or encoding a set of instructions for execution by the machine that cause the machine to perform any one or more of the methods described herein. The term “computer-readable storage medium” shall accordingly be taken to include, but not be limited to, solid-state memories, and optical and magnetic media.

Some portions of the detailed descriptions above are presented in terms of algorithms and symbolic representations of operations on data bits within a computer memory. These algorithmic descriptions and representations are the means used by those skilled in the data processing arts to most effectively convey the substance of their work to others skilled in the art. An algorithm is here, and generally, conceived to be a self-consistent sequence of steps leading to a desired result. The steps are those requiring physical manipulations of physical quantities. Usually, though not necessarily, these quantities take the form of electrical or magnetic signals capable of being stored, transferred, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. Unless specifically stated otherwise, as apparent from the following discussion, it is appreciated that throughout the description, discussions utilizing terms such as “identifying,” “determining,” “storing,” “adjusting,” “causing,” “returning,” “comparing,” “creating,” “stopping,” “loading,” “copying,” “throwing,” “replacing,” “performing,” or the like, refer to the action and processes of a computer system, or similar electronic computing device, that manipulates and transforms data represented as physical (electronic) quantities within the computer system's registers and memories into other data similarly represented as physical quantities within the computer system memories or registers or other such information storage, transmission or display devices.

Examples of the present disclosure also relate to an apparatus for performing the methods described herein. This apparatus may be specially constructed for the required purposes, or it may be a general purpose computer system selectively programmed by a computer program stored in the computer system. Such a computer program may be stored in a computer readable storage medium, such as, but not limited to, any type of disk including optical disks, CD-ROMs, and magnetic-optical disks, read-only memories (ROMs), random access memories (RAMs), EPROMs, EEPROMs, magnetic disk storage media, optical storage media, flash memory devices, other type of machine-accessible storage media, or any type of media suitable for storing electronic instructions, each coupled to a computer system bus.

The methods and displays presented herein are not inherently related to any particular computer or other apparatus. Various general purpose systems may be used with programs in accordance with the teachings herein, or it may prove convenient to construct a more specialized apparatus to perform the required method steps. The required structure for a variety of these systems will appear as set forth in the description below. In addition, the scope of the present disclosure is not limited to any particular programming language. It will be appreciated that a variety of programming languages may be used to implement the teachings of the present disclosure.

It is to be understood that the above description is intended to be illustrative, and not restrictive. Many other embodiment examples will be apparent to those of skill in the art upon reading and understanding the above description. Although the present disclosure describes specific examples, it will be recognized that the systems and methods of the present disclosure are not limited to the examples described herein, but may be practiced with modifications within the scope of the appended claims. Accordingly, the specification and drawings are to be regarded in an illustrative sense rather than a restrictive sense. The scope of the present disclosure should, therefore, be determined with reference to the appended claims, along with the full scope of equivalents to which such claims are entitled.

What is claimed is:

1. A method comprising:
decomposing a profile of a deformation of a substrate into a plurality of harmonics;
identifying, using chuckability reference data, one or more harmonics of the plurality of harmonics having an amplitude above a maximum amplitude capable of being flattened by a predetermined clamping pressure exerted on the substrate by a chuck;
determining, based at least on a subset of the one or more harmonics, settings of a stress-modulation beam;
forming a stress-compensation layer (SCL) on the substrate, wherein the SCL causes a modification of the deformation of the substrate; and
irradiating the SCL with the stress-modulation beam, wherein the stress-modulation beam causes a reduction of the deformation of the substrate.

2. The method of claim 1, further comprising:
performing optical inspection to obtain the profile of the deformation of the substrate.

3. The method of claim 1, wherein the plurality of harmonics comprises at least one of:
one or more Fourier harmonics, or
one or more Zernike polynomials.

4. The method of claim 1, wherein the chuckability reference data identifies, for an individual harmonic of the plurality of harmonics, the maximum amplitude of the individual harmonic capable of being flattened, to within a tolerance amplitude, by the predetermined clamping pressure exerted on the substrate by the chuck.

5. The method of claim 1, wherein the subset of the one or more harmonics excludes short-wavelength harmonics of the plurality of harmonics, the short-wavelength harmonics having a wavelength below a threshold wavelength.

6. The method of claim 1, wherein the subset of the one or more harmonics includes at least one of:
a harmonic associated with an isotropic bow deformation of the substrate, or
one or more harmonics associated with a saddle-shape deformation of the substrate.

7. The method of claim 1, wherein the stress-modulation beam comprises at least one of: a beam of ions, a beam of photons, or a beam of electrons.

8. The method of claim 1, wherein the chuck comprises an electrostatic chuck.

9. The method of claim 1, wherein the settings for the stress-modulation beam comprise one or more of:
a type of particles of the stress-modulation beam,
an energy of the particles of the stress-modulation beam, or
an angle of incidence of the particles of the stress-modulation beam.

10. The method of claim 1, further comprising:
after irradiating the SCL with the stress-modulation beam, clamping the substrate to the chuck; and
performing one or more processing operations on the clamped substrate.

11. A system comprising:
a memory; and
a processing device communicatively coupled to the memory, wherein the processing device causes performance of operations comprising:
decomposing a profile of a deformation of a substrate into a plurality of harmonics;
identifying, using chuckability reference data, one or more harmonics of the plurality of harmonics having an amplitude above a maximum amplitude capable of being flattened by a predetermined clamping pressure exerted on the substrate by a chuck;
determining, based at least on a subset of the one or more harmonics, settings of a stress-modulation beam;
forming a stress-compensation layer (SCL) on the substrate, wherein the SCL causes a modification of the deformation of the substrate; and
irradiating the SCL with the stress-modulation beam, wherein the stress-modulation beam causes a reduction of the deformation of the substrate.

12. The system of claim 11, wherein the plurality of harmonics comprises at least one of:
one or more Fourier harmonics, or
one or more Zernike polynomials.

13. The system of claim 11, wherein the chuckability reference data identifies, for an individual harmonic of the plurality of harmonics, the maximum amplitude of the individual harmonic capable of being flattened, to within a tolerance amplitude, by the predetermined clamping pressure exerted on the substrate by the chuck.

14. The system of claim 11, wherein the subset of the one or more harmonics excludes short-wavelength harmonics of the plurality of harmonics, the short-wavelength harmonics having a wavelength below a threshold wavelength.

15. The system of claim 11, wherein the subset of the one or more harmonics includes at least one of:
a harmonic associated with an isotropic bow deformation of the substrate, or
one or more harmonics associated with a saddle-shape deformation of the substrate.

16. The system of claim 11, wherein the stress-modulation beam comprises at least one of: a beam of ions, a beam of photons, or a beam of electrons.

17. The system of claim 11, wherein the settings for the stress-modulation beam comprise one or more of:
a type of particles of the stress-modulation beam,
an energy of the particles of the stress-modulation beam, or
an angle of incidence of the particles of the stress-modulation beam.

18. The system of claim 11, wherein the operations further comprise:
after irradiating the SCL with the stress-modulation beam, clamping the substrate to the chuck; and
performing one or more processing operations on the clamped substrate.

19. A semiconductor manufacturing system comprising one or more processing chambers, the semiconductor manufacturing system to:
decompose a profile of a deformation of a substrate into a plurality of harmonics;
identify, using chuckability reference data, one or more harmonics of the plurality of harmonics having an amplitude above a maximum amplitude capable of being flattened by a predetermined clamping pressure exerted on the substrate by a chuck;
determine, based at least on a subset of the one or more harmonics, settings of a stress-modulation beam;
form a stress-compensation layer (SCL) on the substrate, wherein the SCL causes a modification of the deformation of the substrate; and
irradiate the SCL with the stress-modulation beam, wherein the stress-modulation beam causes a reduction of the deformation of the substrate.

20. The semiconductor manufacturing system of claim 19, further to:
after irradiating the SCL with the stress-modulation beam, clamp the substrate to the chuck; and
perform one or more processing operations on the clamped substrate.
